(19) United States
(12) Patent Application Publication
(10) Pub. No.: US 2025/0293329 A1
(43) Pub. Date: Sep. 18, 2025

(54) Processes and Apparatus for Recycling Battery Waste Materials

(71) Applicant: Gelion Technologies Pty Ltd, Eveleigh, New South Wales (AU)

(72) Inventors: Andrew Charles Fry, Billingham (GB); Stephen Richard William Johnston, Billingham (GB); Stephen John Shapcott, London (GB); Barbara Breeze, Sonning Common (GB)

(73) Assignee: Gelion Technologies Pty Ltd, Eveleigh, New South Wales (AU)

(21) Appl. No.: 18/859,624

(22) PCT Filed: Apr. 28, 2023
(86) PCT No.: PCT/AU2023/050350

§ 371 Date: Oct. 24, 2024

(30) Foreign Application Priority Data
Apr. 28, 2022 (GB) 2206185.7

(51) Int. Cl. H01M 10/54; C22B 1/216; C22B 1/22; C22B 7/00; C22B 26/12; H01M 10/0525

(52) U.S. Cl. CPC H01M 10/54; C22B 1/216; C22B 1/22; C22B 7/007; C22B 26/12; H01M 10/0525

(57) ABSTRACT

A process for recycling a lithium containing battery waste material, the process comprising the step of heat treating the battery waste material in a vessel, wherein the inner surface of the vessel is formed from a chromium-containing alloy with an aluminium diffusion coating.

### RELATED APPLICATION

This application claims priority from Great Britain patent application No. GB2206185.7 filed on 28 Apr. 2022, the entire contents of which is incorporated herein by reference.

### FIELD The present specification relates to processes for recycling lithium containing battery waste materials and to apparatus suitable for use in such processes.

### BACKGROUND

Lithium-ion batteries are now ubiquitous in modern society, finding use not only in small, portable devices such as mobile phones and laptop computers but also increasingly in electric vehicles. A lithium-ion battery generally includes a graphite anode separated from a cathode by an electrolyte, through which lithium ions flow during charging and discharging cycles. The cathode in a lithium-ion battery may include a lithium transition metal oxide, for example a lithium nickel oxide, lithium cobalt oxide or lithium manganese oxide.

Although lithium-ion and other modern rechargeable batteries offer a promising low-carbon energy source for the future, one concern is that the metals required for their manufacture, such as lithium, nickel, cobalt and/or manganese, often command high prices due to their limited availability and difficulty of extraction from natural sources. There is therefore a need for methods which recycle waste battery materials. Such methods can be grouped into two categories: (i) indirect battery materials recycling, which involves processing waste battery materials, e.g. from used batteries, to recover, separate, and purify component metal species for re-use in a battery material fabrication process; and (ii) direct battery materials recycling, which involves recovering scrap battery cathode material from a battery manufacturing process and processing the battery cathode material for re-use, e.g. by re-lithiating the cathode material, without requiring the cathode material to be separated into its component metal species and re-fabricated.

Both indirect and direct battery materials recycling processes can involve one or more high temperature heat treatment or calcination steps. Heat treatment is typically carried out on a manufacturing scale using industrial furnaces. Roller hearth kilns have been widely used in industrial settings. The use of such kilns typically involves loading a material into a ceramic saggar (or crucible). The saggar then moves through the kiln leading to heat treatment of the material. This type of process involves significant amounts of industrial waste due to the limited lifespan of the ceramic saggars. Energy requirements are also high due to the heat capacity of the saggars.

An alternative is to use a rotary tube furnace, also known as a rotary kiln or a rotary calciner. Tubes for rotary tube furnaces are typically made from metal alloys, although they can be manufactured from other materials such as ceramic. In use, such tubes are typically set at an incline to the horizontal and then rotated around their longitudinal axis. The material to be heat treated is then fed into the upper end of the tube. As the tube rotates the material gradually moves towards the lower end, typically undergoing stirring and mixing. Heat is typically introduced through the tube wall via external heaters which may be electrical or for example gas burners. The rotary kiln may be set up such that there are distinct temperature zones which the material moves through during the heat treatment process. This type of process offers advantages with respect to industrial waste. However, it can have significant drawbacks. Firstly, high temperature contact between the metal tube and lithium containing materials can lead to rapid corrosion of the surface of the metal tube. Secondly, the use of metal tubes, where the surface is actively corroding during operation, can lead to metal contamination of the processed material. For direct battery materials recycling, this can lead to detrimental effects on the performance of the regenerated cathode active material once it is incorporated onto a battery. For indirect battery materials recycling, the presence of further impurity metals can be problematic in downstream separation and purification steps to yield high purity metal salts for re-use in a battery material fabrication process. These drawbacks have led to low levels of adoption of rotary tube furnaces in the cathode materials industry.

EP3362756B1 (BASF SE) describes rotary tubes comprising a double wall construction where the interior wall is a ceramic composite and the external wall is metal. The benefit of such tubes is the reduction of contamination in cathode active materials and protection from corrosion. Such rotary tubes however may suffer from a limited lifespan due to the difference in the thermal expansion co-efficient between the coated base metal and ceramic coating material upon heating to, cooling from, and at the typical kiln operating temperatures. This can lead to degradation of the ceramic surface layer and therefore to peeling from the base metal upon heating, exposing the original metallic material.

Fully ceramic tubes are very delicate and require careful control of temperature changes to prevent fracture, they cannot be manufactured to a suitable size for commercial kilns and cannot be used with build-up removal devices (knockers). In addition, the use of either a monolithic or double wall tube design containing a ceramic material may result in poor heat transfer that may pose operational problems and may result in a shorter lifespan.

There remains a need for improved processes for recycling battery materials, and apparatus suitable for use in such processes, which address the problems set out above.

### SUMMARY OF THE INVENTION

It has been appreciated that during high temperature treatments in the presence of lithium, chromium in metallic materials of construction (MOC) reacts with the lithium, leaching the chromium into the product material. Specifications for chromium in final products are typically low (e.g., <50ppm). Therefore, preventing this chromium addition is key.

Currently, several processes for battery recycling would benefit from the use of a rotary calciner or other metal units in contact with high temperature lithium species. Controlling chromium is of significant importance here, due to tight final product specifications. If metal units cannot be used, ceramic units must be used instead. However, metal units can offer potential environmental benefits (e.g., recyclability, longer life, greater heat transfer, lower energy consumption) than ceramic counterparts.

For battery recycling processes, examples of high temperature processing steps contacting metal and lithium are as follows.

For indirect recycling of battery waste materials such as black mass, it is sometime preferable to go through a pre-treatment stage in which the black mass is heated under a range of gases. Sometimes this is an oxidation, to remove carbon as CO/CO₂. Sometimes the heat treatment is a reduction to reduce metal oxides to metallic form depending on the needs of the downstream processing. These treatments can form Li₂CO₃ or LiOH which can corrode the MOC.

For direct battery materials recycling, where the cathode material has been removed from scrap or cells, the cathode material often needs to be re-lithiated and/or sintered for re-use. Therefore, it is common for such processes to end with a calcination process with the addition of a lithium salt which may corrode the MOC.

The present inventors have surprisingly found that by combining the use of chromium-containing alloys and the application of an aluminium diffusion coating, materials are formed which show good corrosion resistance to lithium containing battery waste materials during high temperature heat treatment and also provide reduced metal contamination of the recycled materials. The coated alloys offer suitable metallurgical and mechanical stability, and suitable external oxidation resistance.

The present specification thus provides a process for recycling a lithium containing battery waste material, the process comprising the step of heat treating the battery waste material in a vessel, wherein the inner surface of the vessel is formed from a chromium-containing alloy with an aluminium diffusion coating.

The use of a vessel formed from a chromium-containing alloy with an aluminium diffusion coating in processes of recycling lithium containing battery waste materials offers process efficiencies whilst achieving low levels of metal contamination, in particular chromium contamination. The use of an aluminium diffusion coating as a means to reduce metal contamination, for example in comparison to ceramic lined or multi-layer vessels, also provides the advantage that the vessel offers a high level of heat transfer and high structural stability during repeated heating and cooling cycles.

The use of a vessel formed from a chromium-containing alloy with an aluminium diffusion coating in processes of recycling lithium containing battery waste materials also offers protection of the underlaying alloy where this would be detrimentally damaged by the presence of sulphur or sulphur containing species that may be present in the battery waste materials.

The present specification also provides an apparatus, such as a rotary furnace tube or a containing, such as a saggar or crucible, with an inner surface formed from a chromium-containing alloy with an aluminium diffusion coating and use of such an apparatus for the recycling of lithium containing battery waste materials.

### DETAILED DESCRIPTION

Preferred and/or optional features of the invention will now be set out. Any aspect of the invention may be combined with any other aspect of the invention unless the context demands otherwise. Any of the preferred and/or optional features of any aspect may be combined, either singly or in combination, with any aspect of the invention unless the context demands otherwise.

The present specification provides a process for recycling lithium containing battery waste materials, such as cathode active materials for secondary lithium-ion batteries, which comprises the step of heat treating the battery waste material in a vessel. Aluminium diffusion coating technology (aluminising/alonizing) is used to reduce corrosion contamination from metallic surfaces in high temperature thermal processing. Aluminising can be used to produce a diffusion coating of metal aluminide on the surfaces of a wide variety of alloy chemistries and produce a range of thicknesses. The aluminide produced is dependent on the base alloy chemistry. Positive results have been seen on 304H, Alloy 800H, Alloy 602CA and C276. However, it is anticipated that a wide selection of alloys would be suitable. Other corrosive species may also be present, and aluminisation is anticipated to provide some corrosions resistance of the MOC from other corrosive species.

This specification thus provides for the application of aluminium diffusion coatings/aluminides for corrosion protection from high temperature high corrosivity lithium species in battery materials recycling processes, primarily to reduce product contamination from metals in the heat transfer/containment surfaces, but additionally to achieve longer equipment lifetime. The specification allows the use of metallic components where previously these may have resulted in unwanted contamination, but also may allow the use of lower cost and/or higher availability MOC's, which is likely to reduce capital costs.

The battery waste material to be recycled may comprises a waste battery cathode material from a used lithium-ion battery, e.g., black mass. Such battery waste materials can be subjected to one or more heat treatments prior to dissolving the battery waste material in acid and recovering, separating, and purifying component metal species for re-use in a battery material fabrication process. In such an indirect battery materials recycling process, it can be advantageous to apply one or more thermal pre-treatments to the waste battery material (e.g., so called “black mass” waste battery material) prior to acid leaching the material to form an acidic aqueous recycling feed and recovering one or more valuable metal species from the acidic aqueous recycling feed. Several different thermal pre-treatments may be applied either individually or in combination. For example, a thermal treatment under an oxidizing atmosphere may be used to remove carbon as CO/CO₂. Alternatively, or additionally, a thermal treatment under a reducing atmosphere may be used to reduce metal oxides to metallic form, which may be advantageous for downstream separation and purification depending on the needs of the downstream processing steps. Alternatively still, one or more thermal treatments may be applied to remove fluorine species from the waste battery material which would otherwise lead to HF generation in downstream processing. HF is very problematic in downstream processing steps as it degrades processing equipment and also presents a serious environmental health and safety risk.

In addition to such thermal treatments for indirect battery materials recycling processes, direct battery materials recycling also advantageously includes one or more thermal processing steps. For example, after cathode material has been removed from scrap battery cathodes, it often needs to be re-lithiated and sintered ready for re-use in a cathode manufacturing process. Therefore, a calcination process with the addition of a lithium salt is often required. As such, the battery waste material may comprise a scrap battery cathode material from a battery manufacturing process which can be re-generated, e.g. by re-lithiation of the scrap battery cathode material. In such a process, one or more thermal treatment steps may be implemented to re-generate the battery cathode material. At least one of the heat treatment steps may be performed concurrently with the re-lithiation of the scrap battery cathode material or following the re-lithiation step to yield the recycled product material.

Typically, the battery waste material comprises a waste cathode active material including a lithium composite metal oxide, such as a lithium transition metal oxide. The term “lithium transition metal oxide” as used herein means a mixed metal oxide comprising lithium and at least one transition metal. Advantageously, the process may be used to recycle lithium transition metal oxides comprising nickel, cobalt, manganese, or combinations thereof. Preferred lithium transition metal oxides are lithiated spinels, cation-disordered rocksalt transition metal oxides, and lithiated transition metal oxides having a layered structure (typically having an α-NaFeO₂-type structure).

In some embodiments, the cathode active material to be recycled is a lithium transition metal oxide with a composition according to the Formula 1:

Li_{c}NiₓCo_{y}Mn_{w}M_{z}O_{2±d} Formula 1

wherein:
0.30≤x<1.0; 0≤y≤0.5; 0≤z≤0.2; 0≤w≤0.7; 0.8≤c≤−1.4; −0.2≤x≤0.2; M is one or more selected from Mg, Al, B, V, Ti, Zr, Sr, Ca, Ce, Cu, Sn, Cr, Fe, Ga, Si, W, Mo, Ta, Y, Sc, Nb, Pb, Ru, Rh and Zn and combinations thereof; or
0.5≤x<1.0, 0≤y≤0.3, 0≤z≤0.1, 0≤w≤0.5, 0.9≤c≤1.1, −0.2≤d≤0.2; M is one or more selected from Mg, Al, B, V, Ti, Zr, Sr, Ca, Ce, Cu, Sn, Cr, Fe, Ga, Si, W, Mo, Ta, Y, Sc, Nb, Pb, Ru, Rh and Zn and combinations thereof; or
0.7≤x≤0.95; 0≤y≤0.2; 0≤z≤0.1; 0≤w≤0.3; 0.9≤c≤1.1; −0.2≤d≤0.2; M is one or more selected from Mg, Al, B, V, Ti, Zr, Sr, Ca, Ce, Cu, Sn, Cr, Fe, Ga, Si, W, Mo, Ta, Y, Sc, Nb, Pb, Ru, Rh and Zn and combinations thereof; or
0.8≤x≤0.95; 0≤y≤0.2; 0<z≤0.05; 0≤w≤0.2; 0.9≤c≤1.1; −0.2≤d≤0.2; M is one or more selected from Mg, Al, B, V, Ti, Zr, Sr, Ca, Ce, Cu, Sn, Cr, Fe, Ga, Si, W, Mo, Ta, Y, Sc, Nb, Pb, Ru, Rh and Zn and combinations thereof; or
0.8≤x≤0.95; 0.05<y≤0.2; 0<z≤0.05; w=0; 0.9≤c≤1.1; −0.2≤d≤0.2; M is one or more selected from Mg, Al, B, V, Ti, Zr, Sr, Ca, Ce, Cu, Sn, Cr, Fe, Ga, Si, W, Mo, Ta, Y, Sc, Nb, Pb, Ru, Rh and Zn and combinations thereof; or
0.8≤x≤0.95; 0.05<y≤0.2; 0<z≤0.05; w=0; 0.9≤c≤1.1; −0.2≤d≤0.2; and M is Mg and optionally one or more selected from Al, B, V, Ti, Zr, Sr, Ca, Ce, Cu, Sn, Cr, Fe, Ga, Si, W, Mo, Ta, Y, Sc, Nb, Pb, Ru, Rh and Zn and combinations thereof.

It may be preferred that in Formula 1, x+y+w=1 or about 1 (e.g. 0.98≤x+y+w≤1.02). It may be preferred that x+y+z+w=1 or about 1 (e.g. 0.98≤x+y+z+w≤1.05 or 1.03).

In some embodiments, the lithium transition metal oxide is a compound of the general formula Li₁₊ₛ(M2)₂O₄₋ᵣ, where r is advantageously in the range from 0 to 0.4, and s is advantageously in the range from 0 to 0.4; M2 is selected from among one or more metals of groups 3 to 132 of the Periodic Table, for example B, Al, Ti, V, Cr, Mn, Fe, Co, Ni, Zn, Mo, with Mn, Co and Ni and combinations thereof being preferred. Particular preference is given to combinations of Ni and Mn, such as doped or un-doped LiMn₂₋ₓNiₓO₄, where x is advantageously in the range from 0 to 1.

The heat treatment is in one of an inert, oxidizing, or reducing atmosphere. The heat treatment can be carried out in a carbon dioxide (CO₂) free atmosphere. For example, the atmosphere may be carbon dioxide free air, which may be a mixture of oxygen and nitrogen. In certain heat treatment steps, the atmosphere is an oxidising atmosphere. As used herein, the term “CO₂-free” is intended to include atmospheres including less than 100 ppm CO₂, e.g. less than 50 ppm CO₂, less than 20 ppm CO₂ or less than 10 ppm CO₂. These CO₂ levels may be achieved by using a CO₂ scrubber to remove CO₂.

For oxidizing heat treatments, it may be preferred that the heat treatment is carried out in a mixture of O₂ and an inert gas, such as N₂. In some heat treatment steps, the mixture comprises N₂ and O₂ in a volume ratio of from 0:100 to 100:0. It may be preferred that the mixture comprises a high concentration of oxygen, for example a volume ratio of inert gas (such as nitrogen) to oxygen of from 30:70 to 5:95. It may be further preferred that the heat treatment is carried out in an atmosphere of at least 20 vol % oxygen (at standard pressure and temperature). In such cases the balance of gas is typically an inert gas, such as nitrogen.

Alternatively, for reductive heat treatments, the heat treatment may be carried out in a mixture of hydrogen and an inert gas, such as N₂. For example, the reducing atmosphere may comprise a volume percentage of hydrogen of: at least 2%, 3%, or 4%; no more than 30%, 20%, or 10%; or within a range defined by any combination of the aforementioned lower and upper limits.

Typically, the heat treatment comprises heating to a temperature of: at least 200° C., 400° C., 500° C. or 600° C.; no more than 1200° C., 1000° C., 800° C., or 700° C.; or within a range defined by any combination of the aforementioned lower and upper limits. For example, the heat treatment may be performed at a temperature in the range of 500 to 1000° C.

Heat treatment of the mixture is typically performed for a period of 1 hour or more, 2 hours or more, 3 hours or more, 4 hours or more, 5 hours or more, or 5.5 hours or more. The heat treatment is typically performed for a period of 20 hours or less, 15 hours or less, 10 hours or less, 8 hours or less, 7 hours or less or 6.5 hours or less. For example, the heat treatment may be performed for between 1 and 20 hours. For example, the heat treatment of the mixture may be carried out at a temperature in the range from 500 to 1000° C. for a period of 1 to 10 hours.

The processes as described hereinbefore comprise heat treatment of a lithium containing battery waste material in a vessel. The type of vessels used for heat treatment during the recycling or waste materials are well known to the skilled person. Such vessels include crucibles, saggars, or other containers into which waste materials are loaded before the vessel is placed into or travels through a kiln, and tubes, such as for a rotary tube furnace through which waste materials travel during the heat treatment process.

In some embodiments the vessel is a container, such as a crucible, tray, or saggar, in particular a saggar suitable for use in an industrial furnace. Typically, such vessels are open (i.e., they do not have a lid), but it may be preferred that they are closed. In some embodiments such vessels have handles, but it may be preferred that they do not. Typically, such vessels have a base that is rectangular or square and it may be preferred that such vessels have a rectangular or square base with rounded angles. The container is configured such that the vessel material in contact with the metal precursor is a chromium-containing alloy with an aluminium diffusion coating, for example the container may be formed essentially of a chromium-containing alloy with an inner (and optionally outer) surface with an aluminium diffusion coating. The use of such vessels offers excellent heat transfer properties in combination with an enhanced lifetime. In some embodiments the container may be used as a liner for a ceramic saggar which, in use, is placed inside a ceramic saggar during heat treatment.

In some embodiments the vessel is a tube for a rotary tube furnace. The shape and dimensions of rotary furnace tubes are well known to the skilled person and such parameters are selected according to the required throughput of material and the required residence time of the material in the tube in order to achieve the desired product properties. Typically, such tubes have a length in the range of from 1 to 40 m. Typically, such tubes have an average diameter of from 100 mm to 1600 mm. The cross section may be circular or non-circular, with circular being preferred. The tube may include internal elements to improve mixing or to retain material in the tube. Such internal elements may be removable or attached to the tube. The tube material in contact with the lithium containing battery waste material as it passes through the tube is formed from a chromium-containing alloy with an aluminium diffusion coating. It may be preferred that the tube is formed essentially of a chromium-containing alloy with an inner surface formed of an aluminium diffusion coating. In the context of the present invention ‘formed essentially of’ means that at least 90% of the weight of the vessel is either the chromium-containing alloy or the aluminium diffusion coating. In some embodiments, the tube for a rotary tube furnace is a multi-layered structure with the inner layer formed from a chromium-containing alloy with an aluminium diffusion coating.

The inner surface of the vessel is formed from a chromium-containing alloy with an aluminium diffusion coating. By ‘inner surface’ is meant herein the surface facing the interior of the vessel which is in contact with the metal precursor during the heat treatment. In the case of a tube for a rotary kiln this is the surface of the tube facing the interior of the tube.

The presence of chromium in the alloy provides oxidation resistance at high temperatures and can increase mechanical strength at high temperature. The use of a chromium-containing alloy additionally provides corrosion resistance which offers benefits if the aluminium diffusion coating degrades towards the end of vessel life.

It may be preferred that the chromium-containing alloy comprises an amount of chromium in the range of and including 0.5 wt % to 40 wt %. A chromium content less than 0.5 wt % does not provide appreciable benefits to strength and oxidation resistance at high temperatures. Chromium contents greater than 40 wt % can lead to poor mechanical properties and higher cost. It may be further preferred that the chromium-containing alloy comprises an amount of chromium in the range of and including 0.5 wt % to 30 wt %, 1 wt % to 30 wt %, 5 wt % to 30 wt %, 10 wt % to 30 wt %, or 15 wt % to 30 wt %.

In some embodiments, the chromium-containing alloy is a stainless steel. It may be further preferred that the chromium-containing alloy is a stainless steel with a chromium content in the range of and including 0.5 wt % to 40 wt %, such as in the range of and including 0.5 wt % to 30 wt %, 1 wt % to 30 wt %, 5 wt % to 30 wt %, 10 wt % to 30 wt %, or 15 wt % to 30 wt %.

It may be preferred that the chromium-containing alloy comprises nickel. The inclusion of nickel offers benefits associated with high strength and creep resistance at high temperatures and metallurgical stability when combined with alloying elements such as chromium. It may be further preferred that the chromium-containing alloy comprises an amount of nickel in the range of and including 1 to 80 wt %. It may be further preferred that the chromium-containing alloy comprises an amount of nickel in the range of and including 5 to 75 wt %, such as 5 to 60 wt %. It may be further preferred that the chromium-containing alloy is a stainless steel with a nickel content in the range of and including 5 to 75 wt %, such as between 5 and 60wt %.

It may be preferred that the chromium-containing alloy comprises chromium in an amount in the range of and including 14 to 30 wt %, such as between 14 and 26 wt % and nickel in the range of and including 5 to 72 wt %, with the mass balance formed from iron and optionally one or more dopant elements, such as one or more of B, Ce, Y, Nb, Zr, Ta, C, Al, Ti, Cu, Mn, Si and N.

It may be preferred that the chromium-containing alloy is selected from ferric stainless alloys (such as ferritic iron-chromium-aluminium (FeCrAl) alloys, for example Kanthal® APM, alloy 439 (UNS S43035), iron-based austenitic stainless alloys (such as alloys 321 (UNS S32100), 347 (UNS S34700), 304/304H/304L (UNS S30400/S30409/S30403), 309 (UNS S30900), 310 (UNS S31000), 314 (UNS S31400), 316/316L/316H/316Ti (UNS S31600/S31603/S31609/S31635), nickel-based austenitic alloys (such as alloys 600 (UNS N06600), 602CA (UNS N 06025), 690 (UNS N0669), C276 (UNS N10276), 625 (UNS N06625)), or iron-nickel-chromium austenitic alloys (alloy 800 (UNS N08800), 800H (UNS N08810), 800HT (UNS N08811). Such alloys offer a combination of high oxidative resistance and strength at high temperature and have alloy chemistry compatible with the aluminium diffusion coating process. It may be further preferred that the chromium-containing alloy is selected from the group of alloys Kanthal APM, 439, 321, 347, 304, 304H, 304L, 309, 310, 314, 316, 316L, 316H, 316Ti, 600, 602CA, 690, C276, 625, 800, 800H, and 800HT. It may be further preferred that the chromium-containing alloy is selected from the group of alloys 304, 800H, 602CA and C276.

The chromium-containing alloys have an aluminium diffusion coating. In the context of the present invention an aluminium diffusion coating is one produced by causing aluminium to react with and/or diffuse into the surface of a metallic substrate, thus, chemically altering the surface of the substrate.

Such coatings may be formed by subjecting the surface of the chromium-containing alloy to an aluminising process (also known as an alonising process or in situ chemical vapour deposition process) leading to the formation of a surface layer comprising a metal aluminide. Typically in such processes, the metal object to be treated is positioned in a container and immersed, filled with, or surrounded with a powder mixture containing aluminium (source), a halide salt such as ammonium chloride, ammonium fluoride, aluminium fluoride, sodium chloride or sodium iodide (the activator), and an inert diluent such as alumina (filler). The container is then sealed, and then heated under an inert atmosphere in a furnace. At elevated temperatures, the aluminium diffuses into the surface of the metal object resulting in a surface layer comprising a metal aluminide. After furnace cooling, the metal object is taken out of the vessel and excess powder is removed. An aluminisation process is described, for example, in WO2005/106064A1 which is incorporated herein by reference. Aluminisation by pack cementation is described in ASTM B875-96 (2018) which is also incorporated herein by reference.

Typically, the aluminium diffusion coating has a thickness of: at least 0.1 μm, 1.0 μm, 5 μm, or 25 μm; no more than 10,000 μm, 5000 μm, 1000 μm, or 500 μm; or within a range defined by any combination of the aforementioned lower and upper limits. For example, the aluminium diffusion coating may have a thickness in the range of 1 to 1000 μm. It may be preferred that the aluminium diffusion coating has a thickness of from around 5 to around 500 μm, such as around 10 to around 300 μm, 25 to 300 μm, or 50 to around 300 μm. The thickness of the aluminium diffusion coating may be assessed by cross-sectioning and assessment of the elemental composition by energy-dispersive X-ray spectroscopy (EDX).

Preferably, the aluminium content of the aluminium diffusion coating is in the range of and including 20 to 45 wt %, or more preferably in the range of and including 20 to 40 wt %. An aluminium content within this range provides a significant reduction in the chromium contamination observed in recycled battery waste materials heat treated in contact with the coated alloy. The aluminium content may be determined by EDX analysis of a cross section of the aluminium diffusion coating. The analysis may be suitably carried out at a position about 1 micron from the coating surface (measured in a direction perpendicular to the surface). The aluminium wt % value is determined based on the total composition detected by the EDX analysis.

### EXAMPLES

The present invention will now be described with reference to the following examples, which are provided to assist with understanding the present invention and are not intended to limit its scope.

### Metal Samples

Four metal samples (stainless steel 304, 800H, 602CA and C276) were coated using a pack cementation aluminium diffusion coating process to provide a surface layer coating containing a metal aluminide with a target coating thickness of 100 μm.

### Calcination Trials—Single Heat Treatment

Each metal sample was placed in an alumina saggar and submerged in 10 grams of a lithium transition metal oxide powder. The same batch of lithium transition metal oxide powder was used throughout. The samples were then placed in a box furnace and calcined by heating to 450° C. at 10° C./min then holding for 120 minutes followed by heating to 700° C. at 10° C./min and holding for 120 minutes. The furnace was then allowed to cool until the sample reached 120° C. in CO₂-free air. After calcination, the metal sample was removed from the lithium transition metal oxide powder and washed in 10 ml of deionised water to remove any attached powder from the metal sample. The lithium transition metal oxide powder was then analysed for trace metal contamination by ICP-MS to determine the amount of chromium and iron contamination added during the calcination. These results were compared to a lithium transition metal oxide powder sample calcined in an alumina saggar containing no metal sample and to a lithium transition metal oxide powder sample calcined in contact with metal samples with no aluminium diffusion coating.

### ICP Method

Samples of the calcined powder were digested in HF. Digestion was performed at 105° C. for a total of 2 hours using a sample digestion block. Analysis for iron and chromium was performed using an Agilent ICP-MS system using an internal standard for calibration.

### Results

Results from the testing of powders are shown in Table 1.

TABLE 1
ICP-MS analysis of the lithium transition
metal oxide powder after heat treatment

Chromium (ppm)

| | 304 | 800 | c276 | 602Ca |
|---|---|---|---|---|
| Aluminised | 18 | <10 | <10 | <10 |
| Untreated | 31 | 15 | <10 | 91 |

From the results, it can be seen that for the 800 H, 602Ca and 304 samples, the amount of chromium added during calcination was reduced by aluminisation of the metal alloy samples. This is particularly evident in the 602Ca results, where a reduction from 91 to <10 ppm chromium was recorded. The results for the C276 sample were within experimental error.

### Calcination Trials—Multiple Heat Treatments

To confirm that aluminising provided a benefit over multiple heat treatments, the metal samples were subjected to further calcinations in contact with batches of the surface-treated lithium transition metal oxide material. The lithium transition metal oxide powder after each calcination was analysed for chromium content by ICP-MS and the measured chromium content values added together for each metal sample to provide a cumulative chromium amount. The results are shown in Table 2. This indicates a significant benefit of aluminising on the level of chromium contamination for each alloy. The levels of iron, copper and zinc contamination of the lithium transition metal oxide material are also consistently low following multiple heat treatments in the presence of the aluminised metal samples.

TABLE 2
ICP-MS analysis of the lithium transition metal oxide powders
in contact with C276 samples after repeated heat treatment

| | Cumulative chromium content |
|---|---|
| Sample | (ppm) |
| C276 untreated (10 heat treatments) | 685 |
| C276-aluminised (10 heat treatments) | 134 |
| 800H untreated (10 heat treatments) | 346 |
| 800H-aluminised (10 heat treatments) | 158 |
| 602CA untreated (5 heat treatments) | 446 |
| 602CA-aluminised (5 heat treatments) | 125 |

### Surface and Cross-Section Analysis

Inspections of the aluminised and untreated metal pieces were performed after the heat treatment to look for evidence of corrosion caused by heating the lithium transition metal oxide material at high temperatures. The aluminised surface of the metal samples were analysed by optical microscopy and scanning electron microscope analysis (SEM). Cross sections of the coupons were also prepared and analysed using energy dispersive x-ray (EDX) analysis. The composition was analysed for aluminium content at a position at a distance of 1 micron from the surface (three measurements taken and the mean value reported). The results for aluminium content are shown in Table 3.

TABLE 3
shows Al content in the surface region
for each of the metal coupons.

| | Al content (wt %) in surface |
|---|---|
| Aluminised Sample | region |
| 602CA | 25 |
| 800H | 34 |
| C276 | 33 |

The test results indicate that metal corrosion during calcination of a lithium transition metal oxide material is reduced by aluminisation of the metal surface and that chromium-containing alloys with an aluminium diffusion coating are suitable materials to use to form vessels used during the recycling of lithium containing battery waste materials.

As used herein, the term “comprising” means “including”. Variations of the word “comprising”, such as “comprise” and “comprises”, have correspondingly varied meanings. As used herein, the terms “including” and “comprising” are non-exclusive. As used herein, the terms “including” and “comprising” do not imply that the specified integer(s) represent a major part of the whole.

Where applicants have defined an invention or a portion thereof with an open-ended term such as “comprising”, it should be readily understood that (unless otherwise stated) the description should be interpreted to also describe such an invention using the terms “consisting essentially of” or “consisting of”. In other words, with respect to the terms “comprising”, “consisting of”, and “consisting essentially of”, where one of these three terms are used herein, the presently disclosed and claimed subject matter may include the use of either of the other two terms. Thus, in some embodiments not otherwise explicitly recited, any instance of “comprising” may be replaced by “consisting of” or, alternatively, by “consisting essentially of”.

The transitional phrase “consisting of” excludes any element, step, or ingredient not specified. If in the claim, such would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, process or method that includes materials, steps, features, components, or elements, in addition to those literally disclosed, provided that these additional materials, steps, features, components, or elements do not materially affect the basic and novel characteristic(s) of the claimed invention. The term “consisting essentially of” occupies a middle ground between “comprising” and “consisting of”.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, the indefinite articles “a” and “an” preceding an element or component of the invention are intended to be non-restrictive regarding the number of instances (i.e., occurrences) of the element or component. Therefore “a” or “an” should be read to include one or at least one, and the singular word form of the element or component also includes the plural unless the number is obviously meant to be singular.

As used herein, with reference to numbers in a range of numerals, the terms “about”, “approximately” and “substantially” are understood to refer to the range of −10% to +10% of the referenced number, preferably −5% to +5% of the referenced number, more preferably −1% to +1% of the referenced number, most preferably −0.1% to +0.1% of the referenced number. Moreover, with reference to numerical ranges, these terms should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, from 8 to 10, and so forth.

Forms of the present invention includes:
1. A process for recycling a lithium containing battery waste material, the process comprising the step of heat treating the battery waste material in a vessel, wherein the inner surface of the vessel is formed from a chromium-containing alloy with an aluminium diffusion coating.
2. A process according to form 1, wherein the vessel is a tube for a rotary tube furnace.
3. A process according to form 1, wherein the vessel is a container, such as a crucible, tray, or saggar.
4. A process according to any one of the preceding forms, wherein the chromium-containing alloy comprises nickel.
5. A process according to form 4, wherein the nickel content of the chromium-containing alloy is between 1 and 80 wt %, such as between 5 and 60 wt %.
6. A process according to any one of the preceding forms, wherein the chromium-containing alloy is selected from the group of alloys Kanthal APM, 439, 321, 347, 304, 304H, 304 L, 309, 310, 314, 316, 316L, 316H, 316Ti, 600, 602CA, 690, C276, 625, 800, 800H, and 800HT
7. A process according to any one of the preceding forms, wherein the aluminium diffusion coating has an aluminium content in the range of 20 to 45 wt %.
8. A process according to any one of the preceding forms, wherein the aluminium diffusion coating has a thickness of: at least 0.1 μm, 1.0 μm, 5 μm, or 25 μm; no more than 10,000 μm, 5000 μm, 1000 μm, or 500 μm; or within a range defined by any combination of the aforementioned lower and upper limits.
9. A process according to any one of the preceding forms, wherein the heat treatment comprises heating to a temperature of: at least 200° C., 400° C., 500° C. or 600° C.; no more than 1200° C., 1000° C., 800° C., or 700° C.; or within a range defined by any combination of the aforementioned lower and upper limits.
10. A process according to any preceding form, wherein the battery waste material comprises a waste battery cathode material from a used lithium-ion battery.
11. A process according to form 10, wherein the battery waste material is subjected to one or more heat treatments prior to dissolving the battery waste material in acid and recovering component metal species for re-use in a battery material fabrication process.
12. A process according to any one of forms 1 to 9, wherein the battery waste material comprises a scrap battery cathode material from a battery manufacturing process.
13. A process according to form 12, which comprises re-lithiation of the scrap battery cathode material.
14. A process according to form 13, wherein the heat treatment is performed concurrently with the re-lithiation of the scrap battery cathode material.
15. A process according to any one of forms 12 to 14, wherein the heat treatment comprises sintering the scrap battery cathode material.
16. A process according to any preceding form, wherein the heat treatment is in one of an inert, oxidizing, or reducing atmosphere.
17. The use of a container, such as a saggar, tray, or crucible, or of a rotary furnace tube with an inner surface formed from a chromium-containing alloy with an aluminium diffusion coating for the recycling of lithium containing battery waste material.

While this invention has been particularly shown and described with reference to certain examples, it will be understood to those skilled in the art that various changes in form and detail may be made without departing from the scope of the invention as defined by the appended claims.

1. A process for recycling a lithium containing battery waste material, the process comprising the step of heat treating the battery waste material in a vessel, wherein the inner surface of the vessel is formed from a chromium-containing alloy with an aluminium diffusion coating.

2. A process according to claim 1, wherein the vessel is a tube for a rotary tube furnace.

3. A process according to claim 1, wherein the vessel is a container, such as a crucible, tray, or saggar.

4. A process according to any one of the preceding claims, wherein the chromium-containing alloy comprises nickel.

5. A process according to claim 4, wherein the nickel content of the chromium-containing alloy is between 1 and 80 wt %, such as between 5 and 60 wt %.

6. A process according to any one of the preceding claims, wherein the chromium-containing alloy is selected from the group of alloys Kanthal APM, 439, 321, 347, 304, 304H, 304 L, 309, 310, 314, 316, 316L, 316H, 316Ti, 600, 602CA, 690, C276, 625, 800, 800H, and 800HT

7. A process according to any one of the preceding claims, wherein the aluminium diffusion coating has an aluminium content in the range of 20 to 45 wt %.

8. A process according to any one of the preceding claims, wherein the aluminium diffusion coating has a thickness of: at least 0.1 μm, 1.0 μm, 5 μm, or 25 μm; no more than 10,000 μm, 5000 μm, 1000 μm, or 500 μm; or within a range defined by any combination of the aforementioned lower and upper limits.

9. A process according to any one of the preceding claims, wherein the heat treatment comprises heating to a temperature of: at least 200° C., 400° C., 500° C. or 600° C.; no more than 1200° C., 1000° C., 800° C., or 700° C.; or within a range defined by any combination of the aforementioned lower and upper limits.

10. A process according to any preceding claim, wherein the battery waste material comprises a waste battery cathode material from a used lithium-ion battery.

11. A process according to claim 10, wherein the battery waste material is subjected to one or more heat treatments prior to dissolving the battery waste material in acid and recovering component metal species for re-use in a battery material fabrication process.

12. A process according to any one of claims 1 to 9, wherein the battery waste material comprises a scrap battery cathode material from a battery manufacturing process.

13. A process according to claim 12, which comprises re-lithiation of the scrap battery cathode material.

14. A process according to claim 13, wherein the heat treatment is performed concurrently with the re-lithiation of the scrap battery cathode material.

15. A process according to any one of claims 12 to 14, wherein the heat treatment comprises sintering the scrap battery cathode material.

16. A process according to any preceding claim, wherein the heat treatment is in one of an inert, oxidizing, or reducing atmosphere.

17. The use of a container, such as a saggar, tray, or crucible, or of a rotary furnace tube with an inner surface formed from a chromium-containing alloy with an aluminium diffusion coating for the recycling of lithium containing battery waste material.
